(19) United States
(12) Patent Application Publication
(10) Pub. No.: US 2015/0160010 A1
(43) Pub. Date: Jun. 11, 2015

(54) Magnetic Sensors and Electronic Compass Using the Same

(71) Applicant: Voltafield Technology Corp., Zhubei City (TW)

(72) Inventors: Tai-Lang Tang, Zhubei City (TW); Cheng Chih Lin, Hsinchu County (TW); Hung Yu Huang, Bade City (TW)

(21) Appl. No.: 14/299,070

(22) Filed: Jun. 9, 2014

(30) Foreign Application Priority Data
Dec. 9, 2013 (TW) 102145040

(51) Int. Cl. G01C 17/02; G01P 15/18; G01R 33/02

(52) U.S. Cl. CPC G01C 17/02; G01R 33/0206; G01P 15/18

(57) ABSTRACT

A magnetic sensor and the electronic compass using the same are provided. The magnetic sensor is configured to sense magnetic components along each axis of a first reference coordinate system, and the first reference coordinate system is associated with the magnetic sensors. When a sensitivity of the magnetic sensor for an axis A of the first reference coordinate system is different from a sensitivity for another axis, the magnetic component Am along the axis A is corrected using the following equation:

Am=Am(n−1)×(Wa−1)/Wa+Am(n)×1/Wa (A)

Therefore, Am(n) designates a current measured magnetic component along the axis A, Am(n−1) designates a previous measured or calculated magnetic component along the axis A, and Wa is a weight value.

### BACKGROUND OF THE INVENTION

1. Field of the Invention

The present invention relates to a magnetic sensors and electronic compass using the same; particularly to a magnetic sensor and electronic compass that can sense accurately in a low cost way.

2. Description of the Prior Art

Along with the Developing of Micro-electromechanical Systems, the application of electronic compass becomes more and more popular. Especially, the application types of the electronic compass become more and more varied when the smart phone becomes popular.

Currently, an electronic compass in the market generally includes an acceleration sensor (G sensor) and a magnetic sensor. The G sensor can sense the acceleration components of electronic compass along the X-axis, Y-axis and Z-axis respectively. It can calculate pitch angle, roll angle, and yaw angle of the electronic compass by analyzing the measured acceleration components and the measured magnetic components.

However, when the magnetic sensor in the market measures the magnetic component along the Z-axis, the sensitivity for the Z-axis is usually lower than the sensitivity for the X-axis and Y-axis. Thus, the measured magnetic component along the Z-axis does not match the actual magnetic component along the Z-axis, thereby causing an error when calculating the yaw angle. This would make the calculated yaw angle does not match the actual yaw angle. A person having ordinary skills in the art usually increases the sensitivity for the Z-axis by improving the manufacturing process of the magnetic sensor, but “improvements for manufacturing process” always needs higher cost. Therefore, how to make the measured magnetic component along the Z-axis closer to the real magnetic component is worth considering to a person having ordinary skills in the art.

### SUMMARY OF THE INVENTION

One object of the present invention is to provide a magnetic sensor and an electronic compass using the same, it can sense accurately in a low cost way.

To achieve the foregoing and other objects, a magnetic sensor is provided. The magnetic sensor is configured to sense magnetic components along each axis of a first reference coordinate system, and the first reference coordinate system is associated with the magnetic sensors. When a sensitivity of the magnetic sensor for an axis A of the first reference coordinate system is different from the sensitivity for the other axis, the magnetic component Am along the axis A is corrected using the following equation:

Am=Am(n−1)×(Wa−1)/Wa+Am(n)×1/Wa (A)

Am(n) designates a current measured magnetic component along the axis A, Am(n−1) designates a previous measured or calculated magnetic component along the axis A, and Wa is a weight value.

In one embodiment, when the sensitivity of the magnetic sensor for the axis A is equal to 1/N of the sensitivity for other axis, Wa is between N/2 and 3N/2. In another embodiment, Wa is equal to N. In the above-mentioned embodiment, the N can be a natural number.

To achieve the foregoing and other objects, an electronic compass is provided. The electronic compass includes the above-mentioned magnetic sensor and an acceleration sensor. It can accurately calculate the magnetic component Am using the above equation (A). Thus, the electronic compass can calculate accurate pitch angle, roll angle or yaw angle.

### BRIEF DESCRIPTION OF THE DRAWINGS

When a person having ordinary skills in the art refers the following figures and detail description, they can clearly understand the above-purpose and advantage of the present invention. Wherein:

FIG. 1 shows the definitions of pitch angle ψ, roll angle ρ and yaw angle θ.

FIG. 2A shows the block diagram of the electronic compass in the first embodiment.

FIG. 2B shows the arrangement of the acceleration sensor and magnetic sensor.

FIG. 3 shows the arrangement of the acceleration sensor and the magnetic sensor in another embodiment.

### DESCRIPTION OF THE PREFERRED EMBODIMENTS

The present invention focuses on an electronic compass, the electronic compass comprises a magnetic sensor. The magnetic sensor can sense Z-axis magnetic field perpendicular to the surface of substrate and X-axis, Y-axis magnetic fields parallel to the surface of substrate. However, the electronic compass of the present invention may further comprise other common structures such as set/reset circuit, various kinds of circuitries such as amplifier, filter, converter . . . etc., shield for shielding unwanted electrical and/or magnetic signals. To explain the present invention clearly and completely without obscurity, the commonly used structures are simply put without detailed descriptions. It is noted that the magnetic sensor of the electronic compass of the present invention can optionally adopt these structures.

The following descriptions illustrate preferred embodiments of the present invention in detail. All the components, sub-portions, structures, materials and arrangements therein can be arbitrarily combined in any sequence despite their belonging to different embodiments and having different sequence originally. All these combinations are falling into the scope of the present invention. A person of ordinary skills in the art, upon reading the present invention, can change and modify these components, sub-portions, structures, materials and arrangements therein without departing from the spirits and scope of the present invention. These changes and modifications should fall in the scope of the present invention defined by the appended claims.

The purpose of figures is to convey concepts and spirits of the present invention, so all the distances, sizes, scales, shapes and connections are explanatory and exemplary but not realistic. Other distances, sizes, scales, shapes and connections that can achieve the same functions or results in the same way can be adopted as equivalents.

In the context of the present invention, the term “magnetic field” or “magnetic field along a specific direction” represents a net magnetic field at a specific location taking effect of magnetic fields from different sources or a magnetic field at a specific location from a specific source without considering other sources or a magnetic component of a specific direction. And, in the context of the present invention, directions “essentially” parallel or “essentially” perpendicular means the angle between two directions is close to 0 or 90 degrees respectively. But, based on consideration of design or deviation of manufacturing, the angle between both has deviation such as 1, 3, 5 or 7 degrees. The deviation can be offset by circuit, vector composition or other method to achieve expected object.

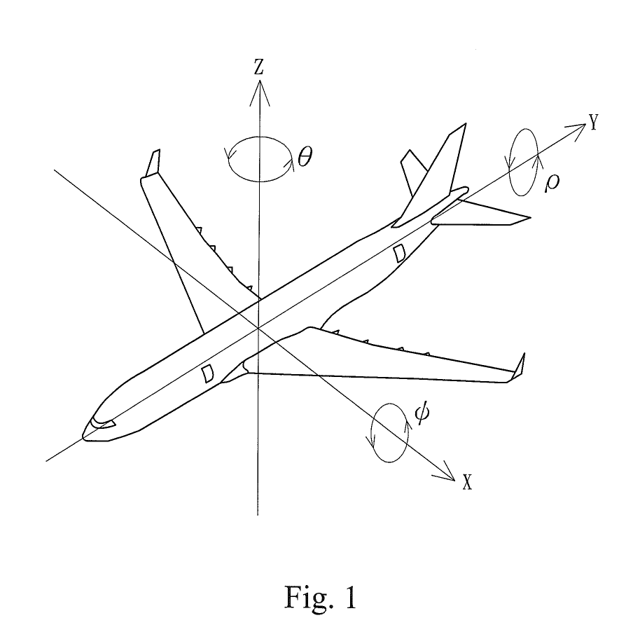

Brief introductions are provided here to define the pitch angle ψ, roll angle ρ and yaw angle θ. Please refer to FIG. 1, the pitch angle ψ is a degree rotated with the X-axis as the center; the roll angle ρ is a degree rotated with the Y-axis as the center; the yaw angle θ is a degree rotated with the Z-axis as the center.

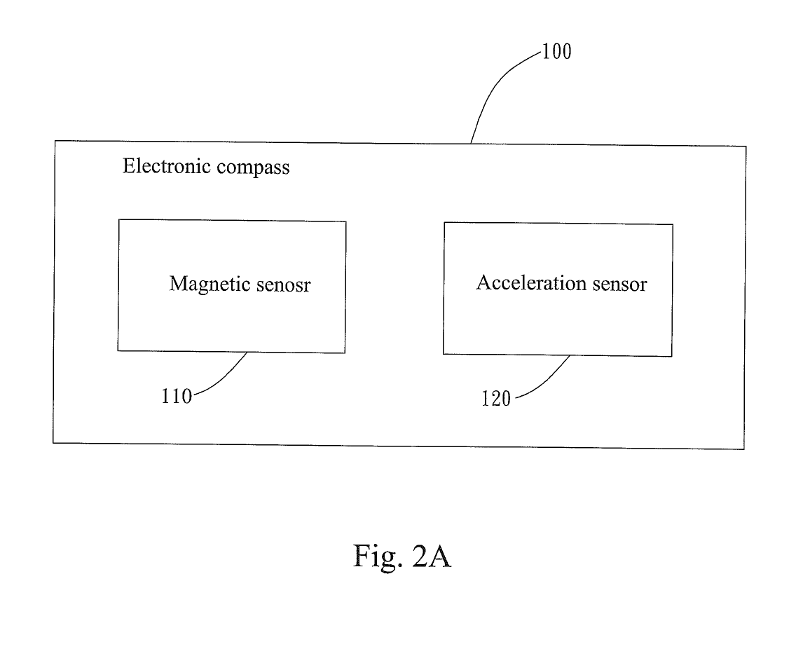

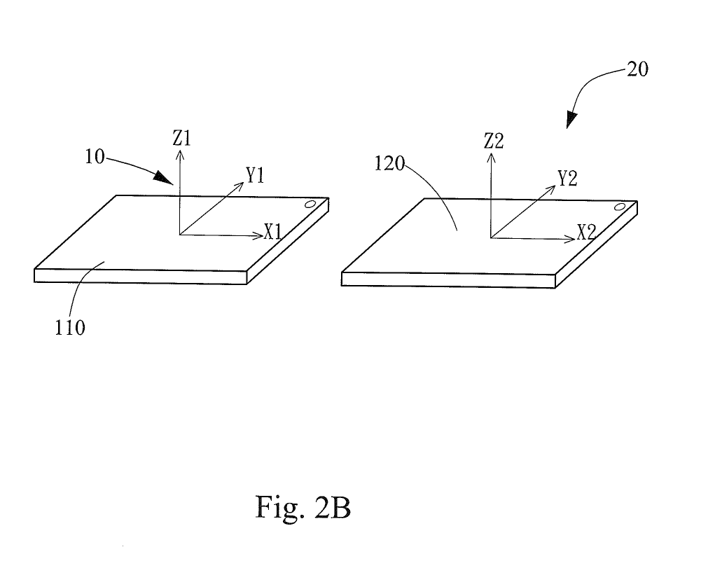

In the following first embodiment, the Z1-axis in the FIG. 2B would be the axis A. The magnetic component Zm along the Z1-axis of the magnetic sensor 110 would be regarded as the magnetic component Am of the above-mentioned equation (A).

Please refer to FIG. 2A, FIG. 2A shows the block diagram of the electronic compass 100 in the first embodiment. The electronic compass 100 comprises a magnetic sensor 110 and an acceleration sensor 120. Please also refer to FIG. 2B, FIG. 2B shows the arrangement of the acceleration sensor and the magnetic sensor. Furthermore, in the first reference coordinate system 10 associated with the magnetic sensor 110, the three axes perpendicular to one another are marked X1, Y1 and Z1 respectively. The origin of the first reference coordinate system 10 is located in the magnetic sensor 110. (For example: at the center of the magnetic sensor 110). Moreover, the first reference coordinate system 10 is linked with the magnetic sensor 110. For example, when the magnetic sensor 110 is moved by a certain distance, the first reference coordinate 10 also would be moved by a certain distance with the magnetic sensor 110.

In the second reference coordinate system 20 associated with the acceleration sensor 120, the three axes perpendicular to one another are marked X2, Y2 and Z2 respectively. The origin of the second reference coordinate 20 is located in the acceleration sensor 120. (For example: at the center of the acceleration sensor 120) Moreover, the second reference coordinate system 20 is linked with the acceleration sensor 120. For example, when the acceleration sensor 120 is rotated by a certain degree, the second reference coordinate system 20 also would be rotated by a certain degree with the acceleration sensor 120. It can be understood from FIG. 2B, the pointing direction of X2-axis, Y2-axis and Z2-axis is the same as the pointing direction of X1-axis, Y1-axis and Z1-axis respectively.

The acceleration sensor 120 is configured to sense the acceleration components to which the electronic compass 100 is subject along the X2-axis, Y2-axis and Z2-axis respectively, that is the Xg, Yg and Zg. Besides, the magnetic sensor 110 is configured to sense the magnetic components along the X1-axis, Y1-axis and Z1-axis where the electronic compass 100 is, that is the Xm, Ym and Zm.

After the acceleration sensor 120 measures the acceleration components Xg and Yg along the X2-axis and Y2-axis, the pitch angle ψ of the electronic compass 100 can be calculated using the following equation (1):

φ=tan⁻¹(Xg/Yg) (1)

Besides, the roll angle ρ of the electronic compass 100 can be calculated using the following equation (2):

ρ=tan⁻¹(−Xg/\sqrt{Xg²+Zg²}) (2)

It is worth noting that the above-equation used to calculate the pitch angle ψ and the roll angle ρ is exemplary. A person having ordinary skills in the art also can calculate the pitch angle ψ and the roll angle ρ using other equations.

The pitch angle ψ and the roll angle ρ of electronic compass 100 can be

The pitch angle ψ and the roll angle ρ of electronic compass 100 can be inferred by the measuring results of the acceleration sensor 120, but the yaw angle θ of the electronic compass 100 has to be inferred by the measuring results of the magnetic sensor 110. However, in this embodiment, since the sensitivity of the magnetic sensor 110 for the Z1-axis is less than that for the X1-axis and the Y1-axis, the magnetic component Zm measured by the magnetic sensor 110 along the Z1-axis can be corrected using the following equation (3):

Zm=Zm(n−1)×(Wz−1)/Wz+Zm(n)×1/Wz; (3)

Zm(n) designates a current measured value (i.e. a value measured by the magnetic sensor 110 along the Z1-axis at the current moment) or a calculated value (i.e. a value calculated by the magnetic sensor 110 along the Z1-axis at the current moment) along the magnetic component Zm. Zm(n−1) represents a previous measured or calculated value of the magnetic component Zm, and Wz is a weight value. Generally speaking, the value of Wz is determined by the difference between the sensitivities of the magnetic sensor 110 for the Z1-axis and X1-axis. In one embodiment, when the sensitivity of the magnetic sensor 110 for the Z1-axis is equivalent to 1/N of the sensitivity for the X1-axis, Wz is between N/2 and 3N/2. In detail, for example, when the sensitivity of the magnetic sensor 110 for the Z1-axis is equivalent to ⅕ of the sensitivity for the X1-axis, Wz can be set between 2.5 and 7.5. Moreover, when the sensitivity of the magnetic sensor 110 for the Z1-axis is equivalent to ⅛ of the sensitivity for the X1-axis, Wz can be set between 4 and 12.

Alternatively, in another embodiment, when the sensitivity of the the X1-axis, Wz is about N. For example, when the sensitivity of the magnetic sensor 110 for the Z1-axis is equivalent to ⅕ of the sensitivity for the X1-axis, Wz is about 5; when the sensitivity of the magnetic sensor 110 for the Z1-axis is equivalent to ⅛ of the sensitivity for the X1-axis, Wz is about 8. In addition, in the above-embodiment, N can be a value other than natural number. In another embodiment, the value of Wz can be adjusted based on designer experience or repeated testing.

After Zm is calculated using the above equation (3), Zm, pitch angle ψ and roll angle ρ can be entered into the following equation (4) and (5):

Xh=Xm×cos ρ−Ym×sin ρ×sin φ−Zm×cos φ×sin ρ (4)

Yh=Ym×cos φ−Zm×sin φ (5)

After Xh and Yh are calculated, the yaw angle θ of the electronic compass 100 can be calculated using the following equation (6):

θ=tan⁻¹(−Xh/Yh) (6)

The range of function tan⁻¹ is limited between −90° to 90°, but the yaw angle θ (0°˜360° can be calculated based on the positive values or negative values of Xh and Yh. For example, a resulted angle −60° is obtained using the equation (6) and if Xh is a positive value, the yaw angle θ can be determined as 300°. Otherwise, if Xh is a negative value, the yaw angle θ can be determined as 240°.

In summary, when the Zm sensed by the magnetic sensor 110 is adjusted using the above equation (3), the yaw angle θ can be calculated accurately using the equation (4), (5), and (6), even though the sensitivity of the magnetic sensor 110 for the Z1-axis is different from the sensitivities for the X1-axis and Y1-axis. Therefore, the sensitivity of the magnetic sensor 110 for the Z1-axis does not need to be improved by improving process, so as to reduce relational cost.

In the above first embodiment, the sensitivity of the magnetic sensor 110 for the Z1-axis is less than the sensitivities for the X1-axis and Y1-axis, so the measured magnetic component Zm along the Z1-axis need to be adjusted. However, in another embodiment, if the sensitivity of the magnetic sensor for the Y1-axis is less than the sensitivities for the X1-axis and Z1-axis, the measured magnetic component Ym along the Y1-axis need to be adjusted using the following equation:

Ym=Ym(n−1)×Wy−1)/Wy+Ym(n)×1/Wy (7)

Ym(n) designates a current measured or calculated magnetic component Ym, Ym(n−1) designates the previous measured or calculated magnetic component Ym, and Wy is a weight value.

Similarly, if the sensitivity of the magnetic sensor for the X1-axis is less than the sensitivities for the Y1-axis and Z1-axis, the measured magnetic component Xm along the Y1-axis need to be adjusted using the following equation:

Xm=Xm(n−1)×(Wx−1)/Wx+Xm(n)×1/Wx (8)

Xm(n) designates a current measured or calculated magnetic component Xm, Xm(n−1) designates the previous measured or calculated magnetic component Xm, and Wx is a weight value.

According to the above principle, this embodiment can be further extended. When the sensitivities for the X1-axis, Y1-axis, and Z1-axis are extended. When the sensitivities for the X1-axis, Y1-axis, and Z1-axis are different, the axis with highest sensitivity can be treated as a reference axis (for example: X1-axis). When the sensitivity for the Y1-axis is equivalent to 1/M of the X1-axis and the sensitivity for the Z1-axis is 1/N of the X1-axis, the measured magnetic component Ym of the magnetic sensor 110 along the Y1-axis can be adjusted using the above equation (7) and the magnetic component Zm along the Z1-axis can be adjusted using the above equation (3). Based on the above-mentioned embodiment, the following equation can be inferred, this equation is configured to correct the magnetic component having different sensitivities.

Am=Am(n−1)×(Wa−1)/Wa+Am(n)×1/Wa;

Am(n) designates a current measured or calculated magnetic component along the axis A, Am(n−1) designates the previous measured or calculated magnetic component along the axis A, and Wa is a weight value.

In the above-mentioned, the determining method of the weight value Wx and Wy is similar to weight value Wz, so it does not need to be explained again. Particularly, the above equations (3), (7), and (8) are embodiments of the equation (A).

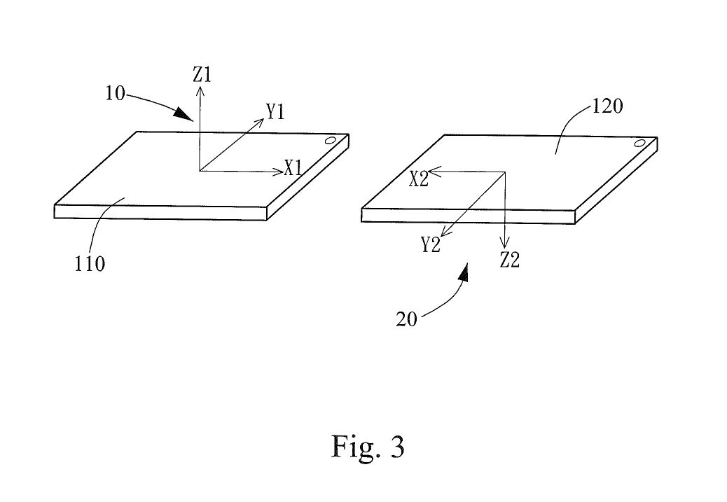

Besides, in the first embodiment, based on the arrangement of the magnetic sensor 110 and the acceleration sensor 120, the X1-axis, Y1-axis and Z1-axis of the first reference coordinate system 10 of the magnetic sensor 110 coincide with the X2-axis, Y2-axis, and Z2-axis of the second reference coordinate system 20 of the acceleration sensor 120, and the pointing direction of the X1-axis, Y1-axis and Z1-axis are the same as that of the adjust the arrangement of the magnetic sensor 110 and the acceleration sensor 120, thus the equations (1), (2), (4)˜(6) may be changed, but the equations (3), (7) and (8) would be the same. For example, when the orientation of the acceleration sensor 120 is adjusted and the pointing direction of the X2-axis, Y2-axis and Z2-axis of the second reference coordinate system 20 are contrary to that of the X1-axis, Y1-axis and Z1-axis of the first reference coordinate system 10 (as shown in FIG. 3), the pitch angle ψ and roll angle ρ of the electronic compass 100 can be calculated respectively using the following equations (9) and (10), the yaw angle θ still can be calculated using the equations (3)˜(6).

φ=tan⁻¹(Yg/Zg) (9)

ρ=tan⁻¹(−Xg/\sqrt{Yg²+Zg²}) (10)

In addition, the yaw angle θ in the first embodiment or second embodiment can be further corrected using the following equation (11):

θ=θ(n−1)×(W_{θ}−1)/W_{θ}+θ(n)×1/W_{θ} (11)

θ(n) designates a current measured or calculated yaw angle θ, θ(n−1) designates the previous measured or calculated yaw angle θ, and W_{θ} is a weight value. W_{θ} can be corrected using the above equation corresponding to different sensitivities for the X-axis, Y-axis or Z-axis of the magnetic sensor 110.

In this embodiment, W_{θ} is equivalent to Wz, but in another situation, Wθ may be equivalent to Wy, Wx or mixed ratio by above three depending on actual situation.

Moreover, in other embodiments, the yaw angle θ is calculated using the equation (6) then the yaw angle θ is corrected using the equation (11) instead of the equation (3).

Those skilled in the art will readily observe that numerous modifications and alternatives of the device and method may be made while retaining the teachings of the invention. Accordingly, the above disclosure should be construed as limited only by the meters and bounds of the appended claims.

I claim:

1. A magnetic sensor, configured to sense the magnetic component along each axis of a first reference coordinate system, and the first reference coordinate system associated with the magnetic sensors;
wherein, when a sensitivity of the magnetic sensor for an axis A of the first reference coordinate system is different from a sensitivity for another axis, a magnetic component Am along the axis A is corrected using the following equation:
Am=Am(n−1)×(Wa−1)/Wa+Am(n)×1/Wa;
wherein, Am(n) designates a current measured magnetic component along the axis A, Am(n−1) designates a previous measured or calculated magnetic component along the axis A, and Wa is a weight value.

2. The magnetic sensor according to claim 1, wherein Wa is between N/2 and 3N/2 when the sensitivity for the axis A is equivalent to 1/N of the sensitivity of another axis.

3. The magnetic sensor according to claim 1, wherein Wa is equivalent to N when the sensitivity for the axis A is equivalent to 1/N of the sensitivity of another axis.

4. The magnetic sensor according to claim 2, wherein N is a natural number.

5. An electronic compass comprising:
a magnetic sensor, configured to sense magnetic components Xm, Ym and Zm of the electronic compass along three axes perpendicular to one another of a first reference coordinate system, the first reference coordinate associated with the magnetic sensor;
an acceleration sensor, configured to sense acceleration components Xg, Yg and Zg along three axes perpendicular to one another of a second reference coordinate system, the second reference coordinate system associated with the acceleration sensor;
wherein, when a sensitivity of the magnetic sensor for an axis Z of the first reference coordinate system is different from a sensitivity for another axis, the magnetic component Zm along the axis Z is corrected using the following equation:
Zm=Zm(n−1)×(Wz−1)/Wz+Zm(n)×1/Wz;
wherein, Zm(n) designates a current measured magnetic component along the axis Z, Zm(n−1) designates a previous measured or calculated magnetic component along the axis Z, and Wz is a weight value.

6. The electronic compass according to claim 5, wherein pointing directions of the three axes perpendicular to one another of the first reference coordinate system is the same as pointing directions of the three axes of the second reference system coordinate, and the pitch angle ψ, the roll angle ρ and the yaw angle θ are calculated by the following equation:
φ=tan⁻¹(Xg/Yg);
ρ=tan⁻¹(−Xg/\sqrt{Xg²+Zg²});
θ=tan⁻¹(−Xh/Yh);
wherein, Xh and Yh are calculated by the following equation:
Xh=Xm×cos ρ−Ym×sin ρ×sin φ−Zm×cos φ×sin ρ;
Yh=Ym×cos φ−Zm×sin φ.

7. The electronic compass according to claim 5, wherein pointing directions of the three axes perpendicular to one another of the first reference coordinate system is contrary to pointing directions of the three axes of second reference coordinate system, and the pitch angle ψ, the roll angle ρ and the yaw angle θ are calculated by the following equation:
φ=tan⁻¹(Xg/Yg);
ρ=tan⁻¹(Xg/\sqrt{Xg²+Zg²});
θ=tan⁻¹(−Xh/Yh);
wherein, Xh and Yh are calculated by the following equation:
Xh=Xm×cos ρ−Ym×sin ρ×sin φ−Zm×cos φ×sin ρ;
Yh=Ym×cos φZm×sin φ.

8. The electronic compass according to claim 6, wherein the yaw angle θ is further corrected using the following equation:
θ=θ(n−1)×(W_{θ}−1)/W_{θ}+θ(n)×1/W_{θ};
wherein, θ(n) designates a current measured or calculated yaw angle θ, θ(n−1) designates a previous measured or calculated yaw angle θ, and W_{θ} is a weight value.

9. The magnetic sensor according to claim 5, wherein when the sensitivity of the magnetic sensor for the axis Z is equivalent to 1/N of the sensitivity for another axis, Wz is equivalent to N.

10. A electronic compass comprising:
a magnetic sensor, configured to sense magnetic components Xm, Ym and Zm of the electronic compass for three axes perpendicular one another of the first reference coordinate system, the first reference coordinate system associated with the magnetic sensor;
a acceleration sensor, configured to sense acceleration components Xg, Yg and Zg for three axes perpendicular to one another of a second reference coordinate system, the second reference coordinate system associated with the acceleration sensor;
wherein, when a sensitivity of the magnetic sensor for an axis Z of the first reference coordinate system is different from a sensitivity for another axis, the yaw angle θ calculated by the electronic compass is corrected using the following equation:
θ=θ(n−1)×(W_{θ}−1)/W_{θ}+θ(n)×1/W_{θ};
wherein, θ(n) designates a current measured or calculated yaw angle θ, θ(n−1) designates a previous measured or calculated yaw angle θ, and W_{θ} is a weight value.
